(19) United States
(12) Patent Application Publication
(10) Pub. No.: US 2009/0025778 A1
(43) Pub. Date: Jan. 29, 2009

(54) SHADING PROTECTION FOR SOLAR CELLS AND SOLAR CELL MODULES

(75) Inventors: Leonid Rubin, Burnaby (CA); Bram Sadlik, Vancouver (CA); Valery Nebusov, Burnaby (CA); Alexander Osipov, New Westminster (CA); Andreas Schneider, Vancouver (CA); Vasily Tarasenko, Burnaby (CA)

Correspondence Address: KNOBBE MARTENS OLSON & BEAR LLP, 2040 MAIN STREET, FOURTEENTH FLOOR, IRVINE, CA, 92614, US

(73) Assignee: Day4 Energy Inc., Burnaby (CA)

(21) Appl. No.: 11/781,588

(22) Filed: Jul. 23, 2007

(51) Int. Cl. H01L 31/052; H01L 31/05

(52) U.S. Cl. 136/246

(57) ABSTRACT

In accordance with one aspect of the invention, there is provided a shading protected solar cell apparatus for use in a solar cell system. The apparatus includes a solar cell having a front side current collector and a back side current collector. The apparatus also includes a bypass diode closely adjacent the back side current collector, the bypass diode having a front side current collector and a back side current collector. The apparatus further includes a first electrical coupling for electrically coupling the front side current collector of the bypass diode to the back side current collector of the solar cell. The apparatus also includes a second electrical coupling for electrically coupling the back side current collector of the bypass diode to the front side current collector of the solar cell, the first and second electrical couplings cooperating to enable a current generated by non-shaded solar cells in the system to be shunted through the bypass diode when the solar cell is shaded. The apparatus further includes a thermal coupling thermally coupling the bypass diode to a back side of the solar cell such that heat generated in the bypass diode due to current shunted through the bypass diode is dissipated by the solar cell sufficiently to avoid burning the solar cell or the bypass diode when the solar cell is shaded.

### BACKGROUND OF THE INVENTION

1. Field of Invention

This invention relates to photovoltaic (PV) cells, in particular, protecting a PV cell and/or PV module against overheating caused by shading or other light obstruction to a PV cell when used as one of a plurality of series-connected PV cells in a PV module.

2. Description of Related Art

A typical PV cell comprises semiconductor material with at least one p-n junction and front and back side surfaces equipped with current collecting electrodes. When illuminated, the cell generates a voltage of approximately 0.6-0.62 V and an electric current of about 34 mA/cm². A plurality of PV cells may be electrically connected in series and/or in parallel arrays to form PV modules that produce higher voltages and/or higher currents. A PV module only performs at optimal efficiency when all the series-connected PV cells are illuminated with approximately similar light intensity. However, if even one PV cell within the module is shaded, while all other cells are illuminated, the overall efficiency of the entire PV module is strongly affected, resulting in a substantial decrease in power output from the PV module.

It was demonstrated in “Numerical Simulation of Photovoltaic Generators with Shaded Cells,” V. Quaschning and R. Hanitsch, 30^{th} Universities Power Engineering Conference, Greenwich, Sep. 5-7, 1995, p.p. 583-586 that PV modules comprised of 36 PV cells can lose up to about 70% of their potential power when as little as 75% of one PV cell of the module is shaded. In addition, the module may be permanently damaged as a result of cell shading.

When a PV cell in a module of series-connected PV cells is shaded, the shaded cell acts as a resistor rather than as a power source. Heating of the shaded cell due to current flow through the resistance of the shaded cell may result in the cell reaching temperatures of 160° C. or higher. These high temperatures may eventually damage the shaded PV cell and destroy the entire PV module.

In order to reduce the problems that can result from shading, practically all conventional PV modules employ bypass diodes that allow current from neighbouring strings to bypass strings containing shaded cells. While power generated by the non-shaded cells in the bypassed string is completely lost, the use of bypass diodes allows the rest of the module to continue producing power and reduces heating of the shaded cell. It is also known to bypass individual cells rather than strings of cells. While bypassing individual cells has been known for many years, and several patents have been issued, several economical and technical problems have impeded the introduction of a practical industrial solution. Generally most solutions employ similar principles in that generally a bypass diode is connected to a PV cell in the opposing direction to the solar cell it protects so that when the solar cell is reverse-biased, the associated bypass diode begins to conduct. This interconnection may employ electrical conductors which connect the diode terminals to the cell terminals or the bypass diode may be directly integrated with the PV cell during fabrication using microelectronics techniques and equipment. Generally, to date, the primary focus of research in this area appears to be to minimize the thickness and area of the bypass diode in order to minimize PV cell breakage during PV module lamination.

U.S. Pat. No. 6,184,458 B1, entitled Photovoltaic Element and Production Method Therefor, to Murakami et al. describes a PV element formed by depositing a photovoltaic element and a thin film bypass diode on the same substrate whereby the bypass diode does not reduce the effective area of the PV element because it is formed under a screen printed current collecting electrode. The production of such cells is complicated and requires precision alignment between the screen printed current collecting electrode and the bypass diode portion. Furthermore the techniques disclosed would not be practical for modern high efficient crystalline silicon PV cells because thin film bypass diodes can not withstand high currents such as about 8.5 A which is a typical current value in a high efficiency 6 inch cell. Furthermore, there appears to be no regard for dissipation of heat that is generated in the bypass diode which could cause overheating and eventually cause the diode to fail and may possibly lead to the destruction of the PV cell and the PV module.

U.S. Pat. No. 5,616,185, 1997, entitled Solar Cell with Integrated Bypass Diode and Method to Kukulka describes an integrated solar cell bypass diode assembly that involves forming at least one recess in a back (non-illuminated) side of a solar cell and placing discrete low-profile bypass diodes in respective recesses so that each bypass diode is approximately coplanar with the back side of the solar cell. The production methods described are complicated and require precision grooves to be cut in the solar cell. The grooves can make the solar cell fragile, increasing cell breakage and yield losses. Again, the techniques described in this reference would not be practical for modern high efficient crystalline silicon PV cells because thin film bypass diodes generally can not withstand the high currents typically found with such cells, or the resultant heating caused by such high currents.

U.S. Pat. No. 6,384,313 B2, 2002, entitled Solar Cell Module and Method of Producing the Same to Nakagawa, et al. describes a method of forming a light-receiving portion of a solar cell element and a bypass diode on the same side of the substrate on which the solar cell is formed. A solar cell with these features allows for series connection of a plurality of solar cell units from only one side of the substrate.

U.S. Pat. No. 5,223,044 1993 entitled Solar Cell Having a By-Pass Diode, to Masahito Asai provides a solar cell having only two terminals and an integrated bypass diode formed on a common semiconductor substrate on which the solar cell is formed. Again, the techniques described in the above two patents require complicated and costly microelectronic technological approaches not easily incorporated into a production line and the bypass diodes created would likely not be able to withstand the high current and resulting heat that can occur when the bypass diode is required to conduct current.

U.S. Pat. No. 6,784,358 B2, 2004, entitled Solar Cell Structure Utilizing and Amorphous Silicon Discrete By-Pass Diode, to Kukulka describes a solar cell structure with protection against reverse-bias damage. The protection employs a discrete amorphous silicon bypass diode with a thickness that does not exceed 2-3 microns so that it protrudes from a surface of the solar cell by only a small distance and does not protrude from the sides of the solar cell. The terminals of the amorphous semiconductor bypass diode are electrically connected by soldering, to corresponding sides of an active semiconductor structure. The soldering of such extremely thin and fragile diodes to the active semiconductor substrate requires extreme accuracy in order to avoid diode breakage. In addition, the amorphous semiconductor bypass diode cannot withstand the high currents and resulting temperatures that can occur in crystalline silicon solar cell systems.

U.S. Pat. No. 5,330,583 entitled Solar Battery Module to Asai, et al. describes a solar battery module that includes interconnectors for series-connecting a plurality of solar battery cells, and one or more bypass diodes which allow output currents of the cells to be bypassed with respect to one or more cells. Each diode is a chip-shaped thin diode and is attached on an electrode of a cell or between interconnectors. More particularly, the chip-shaped bypass diodes are either connected to a front surface of the solar battery or are positioned to the side of a solar battery or are connected to rear surface of a solar battery to protect a string of solar batteries. When the bypass diodes are connected to the front surface, they are soldered directly to one of two parallel conductors which appear to be bus bars, on the front surface of the solar cell. Generally in solar cell design it is an objective to keep the front face of the solar cell clear to keep shading of the front surface to a minimum. Current collecting fingers and bus bars connected to the fingers to gather current from the solar cell are usually the only things acceptable to occlude the front surface, due to their necessity. Generally, fingers and bus bars have width and length dimensions that keep the area they occupy on the front surface to a minimum. Therefore bus bars typically have a narrow width and as a result, the bypass diodes of Asai are necessarily small in width. Although bypass diodes with such a small width and length may be able to carry relatively large currents, due to their small area they tend to heat up due to current flow and impose a localized extreme heat source on the solar cell to which they are mounted.

### SUMMARY OF THE INVENTION

In accordance with one aspect of the invention, there is provided a shading protected solar cell apparatus for use in a solar cell system. The apparatus includes a solar cell having a front side current collector and a back side current collector. The apparatus also includes a bypass diode closely adjacent the back side current collector, the bypass diode having a front side current collector and a back side current collector. The apparatus further includes a first electrical coupling for electrically coupling the front side current collector of the bypass diode to the back side current collector of the solar cell. The apparatus also includes a second electrical coupling for electrically coupling the back side current collector of the bypass diode to the front side current collector of the solar cell, the first and second electrical couplings cooperating to enable a current generated by non-shaded solar cells in the system to be shunted through the bypass diode when the solar cell is shaded. The apparatus further includes a thermal coupling thermally coupling the bypass diode to a back side of the solar cell such that heat generated in the bypass diode due to current shunted through the bypass diode is dissipated by the solar cell sufficiently to avoid burning the solar cell or the bypass diode when the solar cell is shaded.

The bypass diode may include a silicon wafer fragment, the front and back sides of the bypass diode being on opposite sides of the silicon wafer fragment.

The front side current collector of the bypass diode may be generally planar.

The silicon wafer fragment may be formed from the same crystal as the solar cell.

The solar cell may include a surface area and the bypass diode may include a surface area between about 5% to about 25% of the surface area of the solar cell.

The bypass diode may include a surface area of about 10% of the surface area of the solar cell.

The first electrical coupling may include a first electrically insulating film that may have first and second adjacent portions each having a first adhesive coating thereon, the first electrical coupling further including a first plurality of wires having first and second portions secured to the first and second portions respectively of the electrically insulating film by the first adhesive coating, and the first adhesive coating adhesively secures the first portion of the first electrically insulating film to the front side current collector of the bypass diode and the first portion of the first plurality of wires is soldered to the front side current collector of the bypass diode.

The apparatus may further include a first bus bar having first and second oppositely facing surfaces, and the second portion of the first electrically insulating film may be secured to the first surface of the first bus bar by the first adhesive coating and the second portion of the plurality of wires may be soldered to the first surface of the first bus bar.

The first surface of the first bus bar generally faces a back side of the solar cell.

The second oppositely facing surface of the first bus bar generally faces away from the solar cell and the first electrical coupling may further include a second electrically insulating film having first and second adjacent portions each having a second adhesive coating thereon and a second plurality of wires having first and second portions secured to the first and second portions respectively of the second electrically insulating film by the second adhesive coating, and the second adhesive coating adhesively secures the first portion of the second electrically insulating film to the second surface of the first bus bar and the first portion of the second plurality of wires may be soldered to the second surface of the first bus bar.

The second portion of the second electrically insulating film may be secured by the second adhesive coating to the back side current collector of the solar cell and the second portion of the second plurality of wires may be soldered to the back side current collector of the solar cell.

The first electrically insulating film may have first and second oppositely facing surfaces, the first adhesive coating being on the first surface and the thermal coupling may include a thermal adhesive between the second surface of the first electrically insulating film and the back side current collector on the back side of the solar cell to secure the bypass diode to the solar cell while providing for heat transfer therebetween.

The second electrical coupling may include a third electrically insulating film having first and second adjacent portions each having a third adhesive coating thereon and a third plurality of wires having first and second portions secured to the first and second portions respectively of the third electrically insulating film by the third adhesive coating, and the third adhesive coating adhesively secures the first portion of the third electrically insulating film to the back side current collector of the bypass diode and the first portion of the third plurality of wires may be soldered to the back side current collector of the bypass diode.

The apparatus may further include a second bus bar having first and second oppositely facing surfaces, the second portion of the third electrically insulating film being adhesively secured to the first surface of the second bus bar by the third adhesive coating and the second portion of the third plurality of wires being soldered to the first surface of the second bus bar.

The apparatus may further include a fourth transparent electrically insulating film having first and second adjacent portions each having a fourth adhesive coating thereon and a fourth plurality of wires having first and second portions secured to the first and second portions respectively of the fourth transparent electrically insulating film by the fourth adhesive coating, and the fourth adhesive coating adhesively secures the first portion of the fourth transparent electrically insulating film to the second surface of the second bus bar and the first portion of the fourth plurality of wires may be soldered to the second surface of the second bus bar.

The second portion of the fourth transparent electrically insulating film may be adhesively secured to the front side current collector of the solar cell and the second portion of the wires of the fourth plurality of wires may be soldered to the front side current collector of the solar cell.

The second plurality of wires may include a third portion soldered to a bus bar of an adjacent apparatus.

The system may include a plurality of apparatuses.

The solar cell, the bypass diode, the first and second electrical couplings and the thermal coupling may be configured to act as a modular self-protected solar cell apparatus.

At least one of a length and a width of the bypass diode is approximately the same as a corresponding one of a length and a width of the solar cell.

In accordance with another aspect of the invention, there is provided a method for protecting a solar cell against effects caused by shading, in a solar cell system. The method involves electrically coupling a back side current collector of a bypass diode to a front side of the solar cell and electrically coupling a front side current collector of the bypass diode to a back side current collector of the solar cell to enable a current generated by non-shaded solar cells in the solar cell system to be shunted through the bypass diode when the solar cell is shaded. The method also involves disposing the bypass diode closely adjacent the back side current collector of the solar cell and thermally coupling the bypass diode to the back side current collector of the solar cell such that heat generated in the bypass diode due to current shunted through the bypass diode is dissipated by the solar cell sufficiently to avoid burning the solar cell or the bypass diode when the solar cell is shaded.

Electrically coupling may involve causing a first adhesive coating on a first electrically insulating film to adhesively secure a first portion of the first electrically insulating film to the front side current collector of the bypass diode and soldering a first portion of a first plurality of wires embedded in the first adhesive coating to the front side current collector of the bypass diode.

The method may involve causing the first adhesive coating to secure a second portion of the first electrically insulating film to a first surface of a first bus bar and soldering a second portion of the first plurality of wires to the first surface of the first bus bar.

The method may involve causing the first surface of the first bus bar to generally face toward a back side of the solar cell.

The method may involve causing a second oppositely facing surface of the first bus bar to generally face away from the back side of the solar cell.

The method may involve causing a second adhesive coating on a second electrically insulating film to adhesively secure a first portion of the second electrically insulating film to a second surface of the first bus bar and soldering the first portion of the second plurality of wires to the second surface of the first bus bar.

The method may involve causing the second adhesive coating to adhesively secure a second portion of the second electrically insulating film to the back side current collector of the solar cell and soldering a second portion of the second plurality of wires to the back side current collector of the solar cell. Thermally coupling may involve applying a thermal adhesive between a surface of the first electrically insulating film and a back side of the solar cell to secure the bypass diode to the solar cell while providing for heat transfer there between.

The method may involve causing a third adhesive coating to mechanically secure a first portion of a third electrically insulating film to the front side surface of the bypass diode and soldering a first portion of the third plurality of wires to the front side current collector of the bypass diode.

The method may involve causing the third adhesive coating to adhesively secure a second portion of the third electrically insulating film to a first surface of a second bus bar and soldering a second portion of the third plurality of wires to the first surface of the second bus bar.

The method may involve causing a fourth adhesive coating to adhesively secure a first portion of a fourth transparent electrically insulating film to a second surface of the second bus bar and soldering a first portion of a fourth plurality of wires on the fourth transparent electrically insulating film to the second surface of the second bus bar.

The method may involve causing the fourth adhesive coating to adhesively secure a second portion of the fourth plurality of wires to the front side current collector of the solar cell and soldering a second portion of the wires of the fourth plurality of wires to the front side current collector of the solar cell.

The method may involve soldering a third portion of the second plurality of wires to a second bus bar of an adjacent apparatus.

In accordance with another aspect of the invention, there is provided a use of at least a portion of a first solar cell as a bypass diode for a second solar cell, where the second solar cell is series connected to other solar cells a system of solar cells, by electrically coupling a back side current collector of the at least a portion of the first solar cell to a front side current collector of the second solar cell and electrically coupling a front side current collector of the at least a portion of the first solar cell to a back side current collector of the second solar cell to enable a current generated by non-shaded solar cells in the system to be shunted through the at least a portion of the first solar cell when the second solar cell is shaded. There is also provided a use for disposing the bypass diode closely adjacent the back side current collector and thermally coupling the at least a portion of the first solar cell to the back side of the second solar cell such that heat generated in the at least a portion of the first solar cell due to current shunted through the at least a portion of the first solar cell is dissipated by the second solar cell sufficiently to avoid burning the at least a portion of the first solar cell or the second solar cell when the second solar cell is shaded.

In accordance with another aspect of the invention, there is provided a method of protecting a solar cell against shading in a system of series-connected solar cells exposed to light. The method involves electrically coupling a back side current collector of at least a portion of a first solar cell configured to act as a bypass diode to a front side current collector of a second solar cell configured to convert light energy into electrical energy, wherein the second solar cell is series connected to other solar cells in the system, where the other solar cells are configured to convert light energy into electrical energy. The method also involves electrically coupling a front side current collector of the at least a portion of the first solar cell to a back side current collector of the second solar cell such that a current generated by non-shaded solar cells in the system is shunted through the at least a portion of the first solar cell when the second solar cell is shaded. The method further involves disposing the bypass diode closely adjacent the back side current collector of the solar cell. The method also involves thermally coupling the at least a portion of the first solar cell to the back side of the second solar cell such that heat generated in the at least a portion of the first solar cell due to current shunted through the at least a portion of the first solar cell is dissipated by the second solar cell sufficiently to avoid burning the at least a portion of the first solar cell or the second solar cell when the second solar cell is shaded.

In accordance with another aspect of the invention, there is provided a method of generating electric current from light energy. The method involves connecting in series, a plurality of photovoltaic (PV) cell apparatuses to form a PV module. Each PV cell apparatus includes a solar cell having a front side current collector and a back side current collector. Each PV cell apparatus also includes a bypass diode closely adjacent the back side current collector, the bypass diode having a front side current collector and a back side current collector. Each PV cell apparatus further includes a first electrical coupling for electrically coupling the front side current collector of the bypass diode to the back side current collector of the solar cell. Each PV cell apparatus also includes a second electrical coupling for electrically coupling the back side current collector of the bypass diode to the front side current collector of the solar cell, the first and second electrical couplings cooperating to enable a current generated by non-shaded solar cells in the system to be shunted through the bypass diode when the solar cell is shaded. Each PV cell apparatus also includes a thermal coupling thermally coupling the bypass diode to the back side of the solar cell such that heat generated in the bypass diode due to current shunted through the bypass diode is dissipated by the solar cell sufficiently to avoid burning the solar cell or the bypass diode when the solar cell is shaded.

In accordance with another aspect of the invention, there is provided an apparatus for generating electric current from light energy. The apparatus includes a photovoltaic (PV) module comprising a plurality of series-connected PV cell apparatuses. Each PV cell apparatus includes a solar cell having a front side current collector and a back side current collector and a bypass diode closely adjacent the back side current collector, the bypass diode having a front side current collector and a back side current collector. Each PV cell apparatus also includes a first electrical coupling for electrically coupling the front side current collector of the bypass diode to the back side current collector of the solar cell. Each PV cell apparatus further includes a second electrical coupling for electrically coupling the back side current collector of the bypass diode to the front side current collector of the solar cell, the first and second electrical couplings cooperating to enable a current generated by non-shaded solar cells in the system to be shunted through the bypass diode when the solar cell is shaded. Each PV cell apparatus further includes a thermal coupling thermally coupling the bypass diode to the back side of the solar cell such that heat generated in the bypass diode due to current shunted through the bypass diode is dissipated by the solar cell sufficiently to avoid burning the solar cell or the bypass diode when the solar cell is shaded.

The solar cell, the bypass diode, the first and second electrical couplings and the thermal coupling may be configured to act as a modular self-protected solar cell apparatus.

At least one of a length and a width of the bypass diode may be approximately the same as a corresponding one of a length and a width of the solar cell.

In accordance with another aspect of the invention, there is provided a method of generating electric current from light energy. The method involves connecting in series, a plurality of photovoltaic (PV) cell apparatuses to form a PV module. Each PV cell apparatus includes a solar cell having a front side current collector and a back side current collector and a bypass diode closely adjacent the back side current collector, the bypass diode having a front side current collector and a back side current collector. Each PV cell apparatus also includes a first electrical coupling for electrically coupling the front side current collector of the bypass diode to the back side current collector of the solar cell. Each PV cell apparatus further includes a second electrical coupling for electrically coupling the back side current collector of the bypass diode to the front side current collector of the solar cell, the first and second electrical couplings cooperating to enable a current generated by non-shaded solar cells in the system to be shunted through the bypass diode when the solar cell is shaded. Each PV cell apparatus also includes a thermal coupling thermally coupling the bypass diode to the back side of the solar cell such that heat generated in the bypass diode due to current shunted through the bypass diode is dissipated by the solar cell sufficiently to avoid burning the solar cell or the bypass diode when the solar cell is shaded. Each PV cell apparatus further includes grouping the PV cell apparatuses into a plurality of series connected groups each comprised of N series connected PV cell apparatuses and connecting a respective group bypass diode to first and last PV cell apparatuses of each group such that when 0.5 N+1 solar cells in a group are shaded, the bypass diode associated with the group conducts current produced by the remaining groups to bypass the group having shaded solar cells.

The method may involve connecting the bypass diodes associated with respective groups to a heatsink.

The method may involve placing the PV apparatuses into a PV module mount for holding the PV apparatuses.

Connecting the bypass diodes to a heatsink may involve connecting the bypass diodes associated with respective groups to an exterior surface of the PV module mount

In accordance with another aspect of the invention, there is provided an apparatus for generating electric current from light energy. The apparatus includes a photovoltaic (PV) module comprising a plurality of series-connected PV cell apparatuses. Each PV cell apparatus includes a solar cell having a front side current collector and a back side current collector and a bypass diode closely adjacent the back side current collector, the bypass diode having a front side current collector and a back side current collector. Each PV cell apparatus also includes a first electrical coupling for electrically coupling the front side current collector of the bypass diode to the back side current collector of the solar cell. Each PV cell apparatus further includes a second electrical coupling for electrically coupling the back side current collector of the bypass diode to the front side current collector of the solar cell, the first and second electrical couplings cooperating to enable a current generated by non-shaded solar cells in the system to be shunted through the bypass diode when the solar cell is shaded. Each PV cell apparatus also includes a thermal coupling thermally coupling the bypass diode to the back side of the solar cell such that heat generated in the bypass diode due to current shunted through the bypass diode is dissipated by the solar cell sufficiently to avoid burning the solar cell or the bypass diode when the solar cell is shaded. The apparatus also includes the PV cell apparatuses being arranged into a plurality of series connected groups each comprised of N series connected PV cell apparatuses. The apparatus also includes respective group bypass diodes electrically connected to first and last PV cell apparatuses of each group such that when 0.5 N+1 solar cells in a group are shaded, the bypass diode associated with the group conducts current produced by the remaining groups to bypass the group having shaded solar cells.

The bypass diodes associated with respective groups may be connected to a heatsink.

The apparatus may further include a PV module mount for holding the PV apparatuses.

The heatsink may include the PV module mount.

The solar cell, the bypass diode, the first and second electrical couplings and the thermal coupling may be configured to act as a modular self-protected solar cell apparatus

At least one of a length and a width of the bypass diode may be approximately the same as a corresponding one of a length and a width of the solar cell.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention,

FIG. 1 is a cross-sectional view of a shading protected solar cell apparatus according to a first embodiment of the invention.

FIG. 2 is a perspective view of an underside of the apparatus shown in FIG. 1.

FIG. 3 is an electrical schematic diagram of the apparatus shown in FIG. 1 when the apparatus is converting light energy into electrical energy.

FIG. 4 is a schematic diagram of the apparatus shown in FIG. 1 when the solar cell of the apparatus shown in FIG. 1 is shaded causing a bypass diode of the apparatus to enter into a conduction mode.

FIG. 5 is a cross-sectional view of a thermal coupling of the apparatus shown in FIG. 1.

FIG. 6 is a cross-sectional view of a PV module comprising a plurality of series connected apparatuses of the type shown in FIG. 1.

FIG. 7 is a schematic diagram of a PV module comprising a plurality of the apparatuses shown in FIG. 1, connected in series wherein none of the solar cells are shaded.

FIG. 8 is a schematic diagram of a PV module comprising a plurality of the apparatuses shown in FIG. 1, connected in series wherein four of the solar cells are shaded.

FIG. 9 is a schematic diagram of a PV module comprising a plurality of the type apparatuses shown in FIG. 1 wherein the apparatuses are arranged into two groups of series connected apparatuses and in which the current flow is shown for a condition under which all of the PV apparatuses are illuminated by light.

FIG. 10 is a schematic diagram of the PV module shown in FIG. 7 showing current flow when four of the apparatuses of the second group of series connected apparatuses are shaded.

FIG. 11 is a fragmented perspective view of a back side of a solar cell module showing a junction box in which group bypass diodes shown in FIGS. 9 and 10 are mounted.

### DETAILED DESCRIPTION

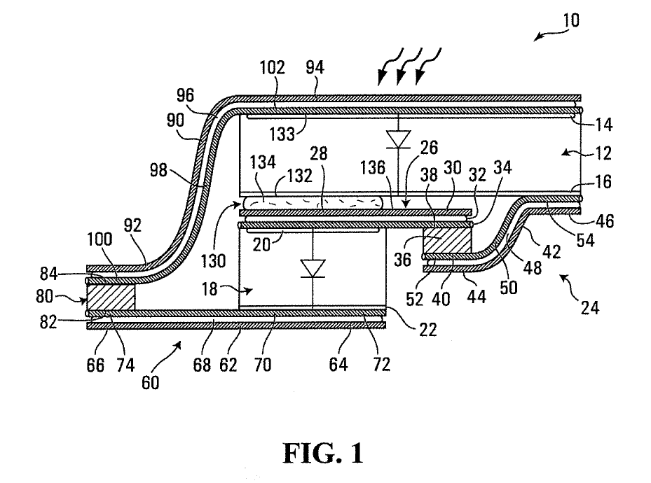

Referring to FIG. 1, a shading protected solar cell apparatus for use in a solar cell system is shown generally at 10. The apparatus 10 includes a solar cell shown generally at 12 having a front side current collector 14 and a back side current collector 16. The front side current collector 14 may include a plurality of screen-printed metallized fingers (not shown) on the front surface of the solar cell 12 and the back side current collector 16 may include a screen printed aluminum metallization layer such as conventionally provided on silicon crystalline solar cells. The front side current collector may include transparent conductive coating such as InOx, SnOx or ZnOx or spattered or evaporated aluminum metallized patterns and the back side current collector may include laser fired contacts or spattered aluminum, or a transparent conductive coating such as InOx, SnOx or ZnOx.

The apparatus 10 further includes a bypass diode shown generally at 18 disposed closely adjacent the back side current collector 16 and in thermal contact therewith as will be described below. The bypass diode 18 has a front side current collector 20 and a back side current collector 22. The front side current collector 20 may include a screen printed metallization pattern and since the bypass diode will not and need not receive light, the metallization pattern on the front side need not be concerned with the admission of light to the front side surface of the bypass diode. The back side current collector 22 may be formed using any of the methods described above in connection with the back side current collector of the solar cell 12. In this embodiment, the bypass diode 18 is formed from the same material as the solar cell 12 and may be formed from a fragment of the same wafer from which the solar cell is produced. Thus both the solar cell 12 and bypass diode 18 may have similar electrical properties.

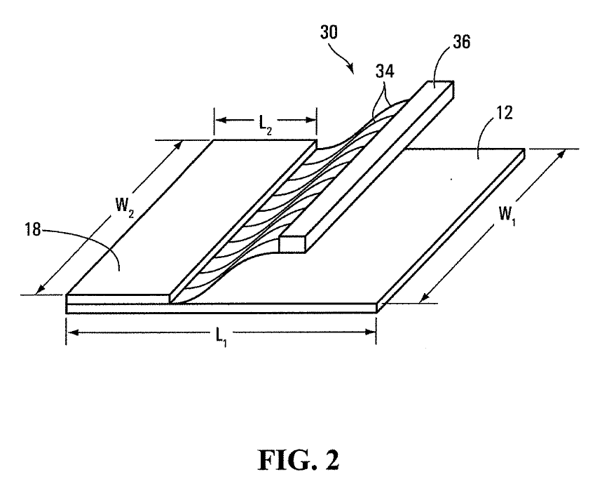

Referring to FIG. 2, the solar cell 12 has a length L1 and a width W1 that define an area of the solar cell. In addition, the bypass diode 18 also has a length and a width, L2 and W2 respectively, which define an area of the bypass diode. Desirably the length L2 and width W2 of the bypass diode 18 are selected such that the area of the bypass diode is approximately about 5% to 25% of the area of the solar cell 12. Good results have been obtained where the area of the bypass diode 18 is approximately 10% of the area of the solar cell 12 and at least one of the length and width of the bypass diode is approximately the same as a corresponding one of the length or width respectively of the solar cell.

Referring back to FIG. 1, the apparatus 10 further includes a first electrical coupling 24 for electrically coupling the front side current collector 20 of the bypass diode 18 to the back side current collector 16 of the solar cell 12. In this embodiment, the first electrical coupling 24 includes a first electrically insulating film 26 having first and second adjacent portions 28 and 30, each having a first adhesive coating 32 thereon. The first electrically insulating film 26 desirably has high ductility, good insulating characteristics, thermal stability and resistance to shrinkage. It may be optically transparent but need not be. Examples of suitable materials include cellophane, RTM, rayon, acetate, fluororesin, polysulfone, epoxy resin, Mylar®, polyamide resin, polyvinyl fluoride film, Tedlar® RTM, and ETFE fluoropolymer resin (Tefzel.RTM®). The first adhesive coating 32 may have a thickness of about 25 μm to about 50 μm, for example. Desirably, the first adhesive coating 32 has a softening temperature ranging from about 90° C. to about 110° C. and has good adhesion to preliminarily primed polymeric films and the surface of the bypass diode 18. Exemplary materials include acrylic adhesive materials, rubber adhesive, silicon adhesive materials, polyvinyl ether adhesive materials, thermal plastic adhesive materials and epoxy adhesive materials.

A first plurality of parallel, spaced apart wires, one of which is shown at 34, is secured to the first electrically insulating film 26 by the first adhesive coating 32 such that portions of the wires are embedded in the first adhesive coating while other portions of the wires are not embedded in the first adhesive to provide for contacting the wires to conductive surfaces. The wires extend from the first portion 28 to the second portion 30. An exemplary film having the above described adhesive coating and wires embedded therein is described in published PCT application No. PCT/CA03/01278 published Nov. 3, 2004 under Publication Number WO/2004/021455 which is incorporated herein by reference. Film with the adhesive and plurality of wires embedded therein, as described in the above mentioned PCT publication can be pre-ordered from Day4 Energy Inc. of Burnaby, B.C., Canada and used in assembling the shading protected solar cell apparatus described herein.

The first adhesive coating 32 adhesively secures the first portion 28 of the first electrically insulating film 26 to the front side current collector 20 of the bypass diode 18 and a first portion of the first plurality of wires 34 is soldered to the front side current collector of the bypass diode. Soldering of the first plurality of wires 34 to the front side current collector 20 of the bypass diode 18 may be accomplished simultaneously with causing the first adhesive coating to adhere to the front side current collector by heating and pressing the first portion 28 of the first electrically insulating film 26 onto the front side current collector 20.

Heating may involve heating the first electrically insulating film, adhesive and pre-coated wires 34 to a temperature of about 125° C. to about 160° C. Pressing may involve pressing the first electrically insulating film 26 and wires 34 onto the front side current collector 20 with a pressure of up to about 15 psi.

Thus, the first plurality of wires 34 is in electrical contact with the front side current collector 20 of the bypass diode 18 and is secured thereto by solder and in addition, the first electrically insulating film 26 is secured to the front side current collector by the first adhesive coating 32 such that the second portion 30 of the first electrically insulating film extends beyond the outer extremity of the bypass diode 18.

The first electrical coupling 24 further comprises a first bus bar 36 which may be comprised of a copper conductor, for example, having first and second oppositely facing surfaces 38 and 40 respectively and cross-sectional dimensions of about H 0.05-0.2 mm×about W 2-8 mm, for example. The first and second oppositely facing surfaces 38 and 40 may be flat planar surfaces, for example. The first surface 38 of the first bus bar 36 generally faces a back side 132 of the solar cell 12. The second portion 30 of the first electrically insulating film 26 is secured to the first surface 38 of the first bus bar 36 by the first adhesive coating 32 and a second portion of the first plurality of wires 34 is secured to the first surface of the first bus bar by soldering the wires thereto. Soldering and causing the adhesive to adhere to the first surface 38 of the first bus bar 36 may be accomplished by heating and pressing at the same time the first electrically insulating film 26 is secured to the front side current collector 20 of the bypass diode 18, or at an earlier or later time.

The first electrical coupling 24 further includes a second electrically insulating film 42 same as the first electrically insulating film 26. The second electrically insulating film 42 has first and second adjacent portions 44 and 46 respectively and a second adhesive coating 48 on each of the first and second adjacent portions 44 and 46. A second plurality of wires 50 having first and second portions 52 and 54 is secured to the first and second portions 44 and 46 respectively of the second electrically insulating film 42 by the second adhesive coating 48. The second adhesive coating 48 adhesively secures the first portion 44 of the second electrically insulating film 42 to the second surface 40 of the first bus bar 36 and the first portion 52 of the second plurality of wires 50 is soldered to the second surface of the first bus bar. Soldering and causing the second adhesive coating 48 to adhere to the second surface may be accomplished by heating and pressing as described above, for example.

The second portion 46 of the second electrically insulating film 42 is secured by the second adhesive coating 48 to the back side current collector 16 of the solar cell 12 and the second portion 54 of the second plurality of wires 50 is soldered to the back side current collector 16 of the solar cell 12, in the same manner as described above. Thus, there is an electrical connection between the front side current collector 20 of the bypass diode 18 through the first plurality of wires 34 to the first bus bar 36 and then to the second plurality of wires 50 to the back side current collector 16 of the solar cell 12.

Still referring to FIG. 1, the apparatus further includes a second electrical coupling, shown generally at 60, for electrically coupling the back side current collector 22 of the bypass diode 18 to the front side current collector 14 of the solar cell 12. The second electrical coupling 60 comprises a third electrically insulating film 62 which may be the same as the first and second electrically insulating films 26 and 42. The third electrically insulating film has first and second portions 64 and 66 and a third adhesive coating 68 thereon. A third plurality of wires 70 having first and second portions 72 and 74 is secured to the third electrically insulating film 62 by the third adhesive coating 68 and the third adhesive coating adhesively secures the first portion 64 of the third electrically insulting film 62 to the back side current collector 22 of the bypass diode 18. In addition, the first portion 72 of the third plurality of wires 70 is soldered to the back side current collector 22 of the bypass diode 18.

The second electrical coupling 60 further includes a second bus bar shown generally at 80 having first and second oppositely facing surfaces 82 and 84. The second portion 66 of the third electrically insulating film 62 is adhesively secured to the first surface 82 of the second bus bar 80 by the third adhesive coating 68 and the second portion 74 of the third plurality of wires 70 is soldered to the first surface 82 of the second bus bar 80. The back side current collector 22 of the bypass diode 18 is thus in electrical contact with the second bus bar 80 through the third plurality of wires 70.

The second electrical coupling 60 further includes a fourth electrically insulating film 90 same as the first electrically insulating film 26 described above having first and second adjacent portions 92 and 94 respectively, with the exception that at least the second portion 94 must be transparent to light. Each of these portions has a fourth adhesive coating 96 thereon and a fourth plurality of wires 98 having first and second portions 100 and 102 is secured to the first and second portions 92 and 94 of the fourth electrically insulating film 90 by the fourth adhesive coating 96. The fourth adhesive coating 96 adhesively secures the first portion 92 of the fourth electrically insulating film 90 to the second surface 84 of the second bus bar 80 and the first portion 100 of the fourth plurality of wires 98 is soldered to the second surface 84 of the second bus bar.

The second portion 94 of the fourth electrically insulating film 90 is adhesively secured to the front side current collector 14 of the solar cell 12 and the second portion 102 of the fourth plurality of wires 98 is soldered to the front side current collector 14 of the solar cell. Thus, the second bus bar 80 is in electrical contact with the front side current collector 14 of the solar cell 12 through the fourth plurality of wires 98. At least the second portion 94 of the fourth electrical insulating film 90 must be transparent to permit light to pass through to reach the solar cell 12. All other electrically insulating films described herein, including the first, second, and third electrically insulating films 26, 42, and 62 can be transparent but need not be.

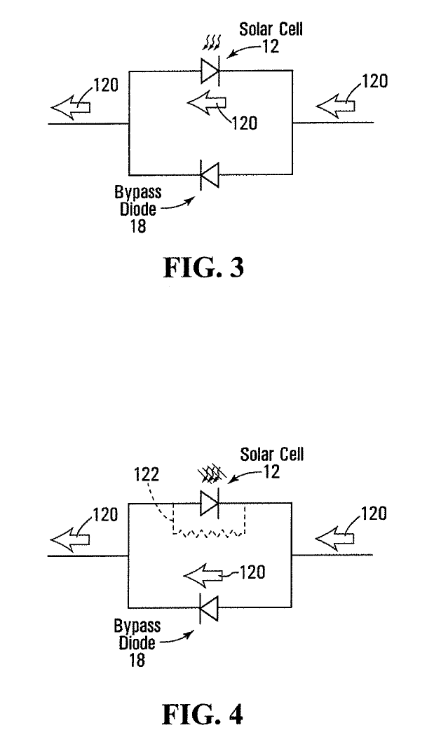

In effect, the first and second electrical couplings 24 and 60 act to connect the front side current collector 20 of the bypass diode 18 to the back side current collector 16 of the solar cell 12 and to connect the back side current collector 22 of the bypass diode to the front side current collector 14 of the solar cell. Thus, the solar cell 12 and bypass diode 18 are connected in opposing arrangements as shown in FIG. 3.

Referring to FIG. 3, it will be appreciated that when the solar cell 12 is illuminated along with other solar cells in the system to which the shading protected solar cell apparatus of FIG. 1 is connected, current shown generally at 120 generated by all of the solar cells in the system will flow through the solar cell and not the bypass diode.

Referring to FIG. 4, when the solar cell 12 is shaded, it no longer acts as a current source but rather as a resistance, in which case a voltage builds up across the resistance, sufficient to forward bias the bypass diode 18 to cause the current 120 to be conducted through the bypass diode and bypass the resistance 122 presented by the solar cell 12. Thus, referring back to FIG. 1, the first and second electrical couplings 24 and 60 respectively co-operate to enable a current generated by non-shaded solar cells in the system to be shunted through the bypass diode 18 when the solar cell 12 is shaded.

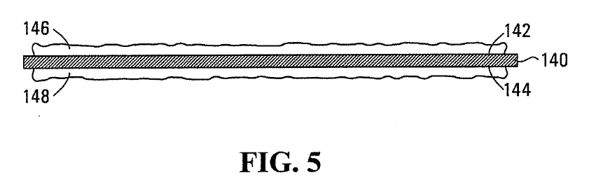

Referring back to FIG. 1, the apparatus further includes a thermal coupling shown generally at 130 that thermally couples the bypass diode 18 to a back side 132 of the solar cell 12 such that heat generated in the bypass diode 18 due to current shunted therethrough is dissipated by the solar cell sufficiently to avoid burning the solar cell or the bypass diode when the solar cell is shaded. To effect this thermal coupling 130, in this embodiment, a thermal adhesive 134 is disposed between a rear surface 136 of the first electrically insulating film 26 to adhesively and thermally secure the first electrically insulating film to the back side current collector 16 of the solar cell 12. Suitable thermal adhesives based on silicon, epoxy, or thermal plastic material are readily available and may be used as the thermal adhesive 134. The thermal adhesive layer should be sufficiently thick to secure the first electrically insulating film 26 to the back side current collector 22 of the solar cell 12 and sufficiently thin to provide minimum resistance to heat conduction between the first electrically insulating film and the back side current collector. A layer of thermal adhesive about 50 μm to about 100 μm in thickness provides acceptable results. Alternatively, referring to FIG. 5, the thermal coupling 130 may include a polymeric film 140 having a low thermal resistance and having first and second oppositely facing sides 142 and 144 respectively. The polymeric film 140 may be formed from polyester and may have a thickness of between about 12 micrometers to about 25 micrometers. The first side 142 may face the back side current collector 16, shown in FIG. 1, while the second side 144 may face the front side current collector 20 on the bypass diode 18 shown in FIG. 1.

Referring back to FIG. 5 on the first side 142 of the polymeric film 140, there is provided a first adhesive layer 146 that may be comprised of ethylene vinyl acetate. This first adhesive layer 146 may have a thickness of between about 25 μm to about 50 μm.

The second side 144 is also coated with a second layer 148 of adhesive which may also be formed from ethylene vinyl acetate and also having a thickness of between about 25 μm to about 50 micrometers. Desirably, the total thickness of the thermally conductive polymeric film 140 and the first and second adhesive layers 146 and 148 will be about 100 μm to provide for sufficient adhesion while providing for a low impedance to thermal conduction between the first electrically insulating film 26 and the back side current collector 16 of the solar cell 12.

Desirably, regardless of which thermal coupling is used, i.e., that shown in FIG. 1 or that shown in FIG. 5, or equivalent thermal couplings the thermal adhesive 134 or thermally conductive polymeric film 140 extends over the entire surface of the bypass diode 18 to provide for heat transfer between the bypass diode 18 and the solar cell 12 over a relatively large area. This has the effect of distributing the heat from the bypass diode 18 over a large area of the solar cell 12, thereby avoiding localized hot spots in the solar cell which could be potentially damaging to it. Furthermore, the use of the same material used to make the wafer from which the solar cell 12 is made allows for use of waste wafer as bypass diodes 18 thereby improving the utility of wafers produced for making solar cells. Only fragments of the wafer are required and good light to electrical conversion efficiency is not required. Therefore wafers that are rejected as solar cells 12 due to poor light to electrical conversion efficiency can be broken into fragments and used as bypass diodes 18.

In addition, since the bypass diode 18 is disposed closely adjacent the back side current collector 16 it does not shade the front side 133 of the solar cell 12 and provides no blocking whatsoever to light impinging upon the front side of the solar cell. Furthermore, disposing the bypass diode 18 closely adjacent the back side current collector 16 of the solar cell 12 facilitates thermally coupling the bypass diode to the solar cell as described. The use of the first, second, third and fourth electrically insulating films 26, 42, 62 and 90 facilitates easy connection of the bypass diode 18 to the solar cell 12 it protects and as will be seen below, to other solar cells in the system. The solar cell 12, bypass diode 18, electrically insulating films 26, 42, 62, and 90 and bus bars 36 and 80 form a unitary device that may be regarded as a modular, self protected PV cell unit.

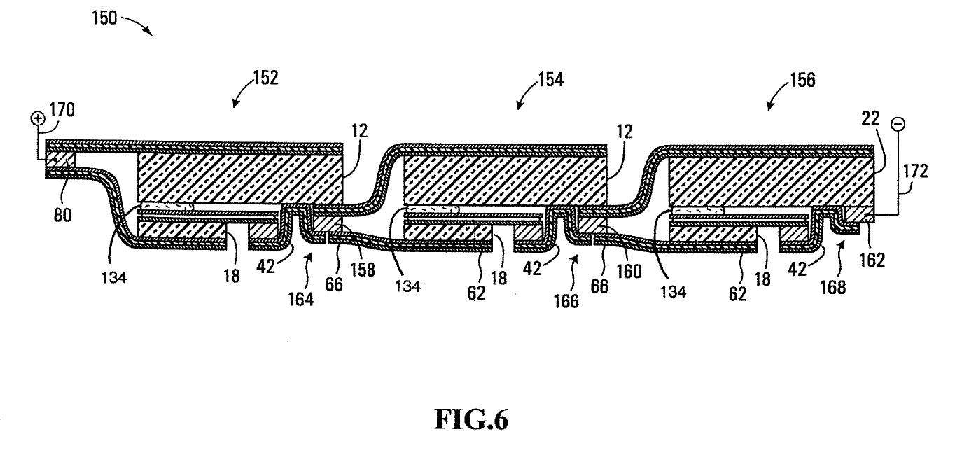

Referring to FIG. 6, a photovoltaic (PV) module is shown generally at 150 and includes first, second and third PV cell apparatuses 152, 154, and 156 of the type shown in FIG. 1. However, each PV cell apparatus 152, 154, and 156 includes a third bus bar 158, 160, and 162 respectively to which the third portions 164, 166, and 168 respectively of the second electrically insulating film 42 in each PV cell apparatus is connected. In addition, the second portions 66 of the third electrically insulating film 62 of PV cell apparatuses 154 and 156 are connected to the third bus bar 158 and 160 respectively. The third bus bar 158 and 160 therefor act as the second bus bar 80 referred to in FIG. 1 of the PV cell apparatuses 154 and 156 respectively. The second bus bar 80 of the first PV cell apparatus 152 is connected as described in connection with FIG. 1 and acts as a first terminal to which a wire, 170 for example, may be connected to act as a positive terminal for the module. The third bus bar 162 associated with the third PV cell apparatus 156 may be connected by a wire 172 to act as a negative terminal for the module 150. Thus, the use of the third portions 164, 166, and 168 of the second electrically insulating film 42, and the use of the third bus bars 158, 160, and 162 in the manner shown serves to connect the PV cell apparatuses 152, 154, and 156 in series to additively sum the voltage produced by each solar cell 12 of each apparatus while each solar cell has an associated bypass diode 18 to provide individual shading protection therefor. Thus, for example, should the second PV cell apparatus 154 become shaded, the associated solar cell 12 will no longer generate current and will act as a resistor, in which case current generated by the PV cell apparatuses 152 and 156 will flow through the bypass diode 18 associated with apparatus 154 and heat generated in the bypass diode 18 will be dissipated to the solar cell associated with the second PV cell apparatus 154 without causing excessive overheating of the solar cell and the bypass diode of the second PV cell apparatus 154. When the solar cell 12 associated with apparatus 154 is no longer shaded, the solar cell begins to generate power in response to light and resumes adding to the net voltage produced by the module 150. It will be appreciated that each PV cell apparatus 152, 154, and 156 has a similar bypass diode 18 and thus each respective solar cell 12 is protected from shading in the manner described above. It will also be appreciated that a greater number of PV cells may be connected in series in the manner shown in FIG. 6

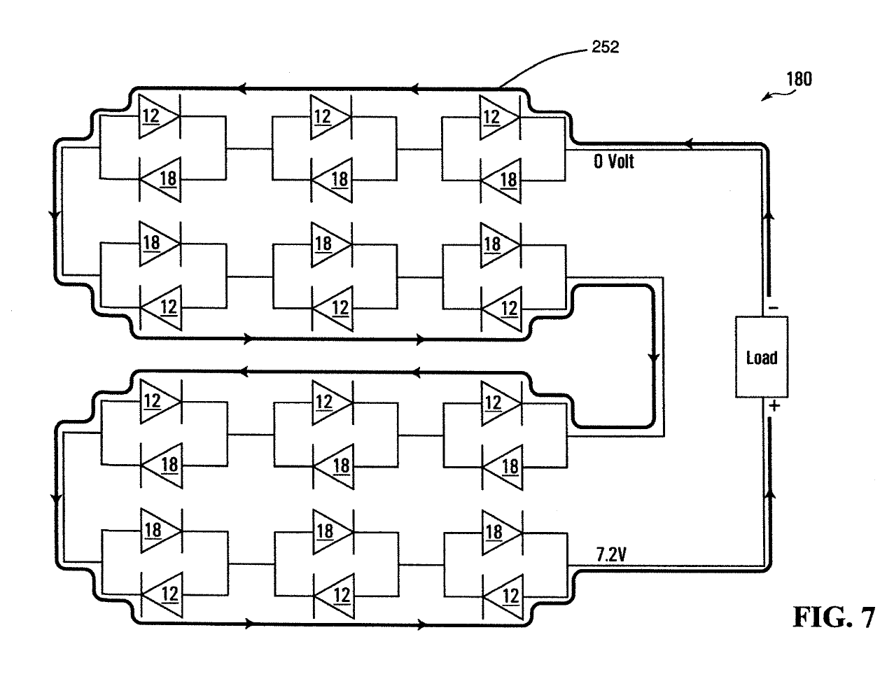

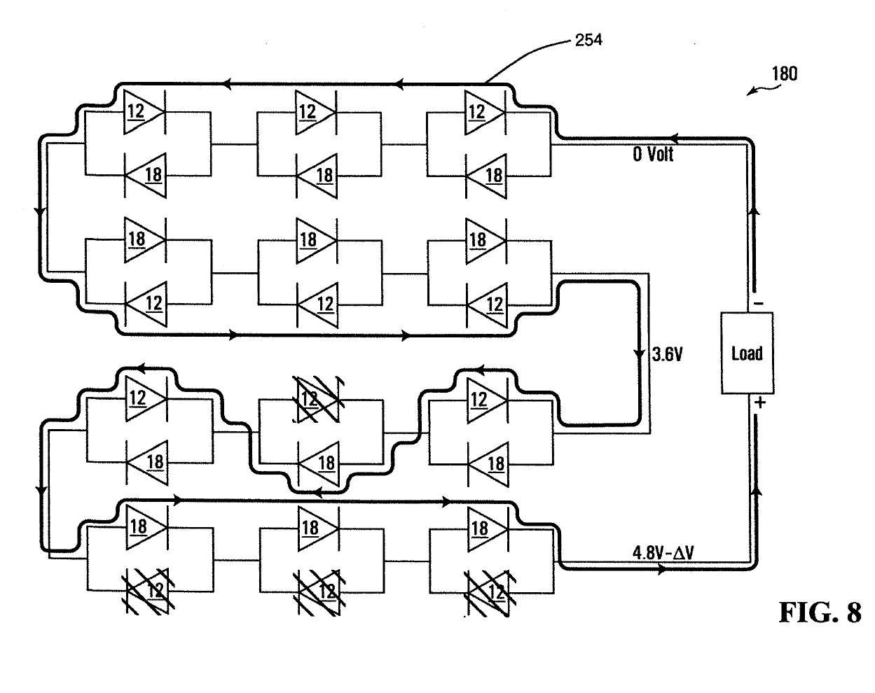

Referring to FIG. 7, an electrical schematic diagram of a photovoltaic module apparatus for generating electric power from light energy is shown generally at 250 and includes a plurality of series connected PV cell apparatuses of the type described in connection with FIG. 1. When all solar cells are illuminated relatively evenly, current flows as shown by arrow 252. When any solar cell is shaded, that solar cell acts as a resistance across which a voltage is developed. When this voltage reaches a breakdown voltage of the associated bypass diode, the bypass diode begins to conduct, bypassing current around the shaded solar cell as shown at 254 in FIG. 8 wherein for solar cells are shaded and each associated bypass diode conducts the current of the system.

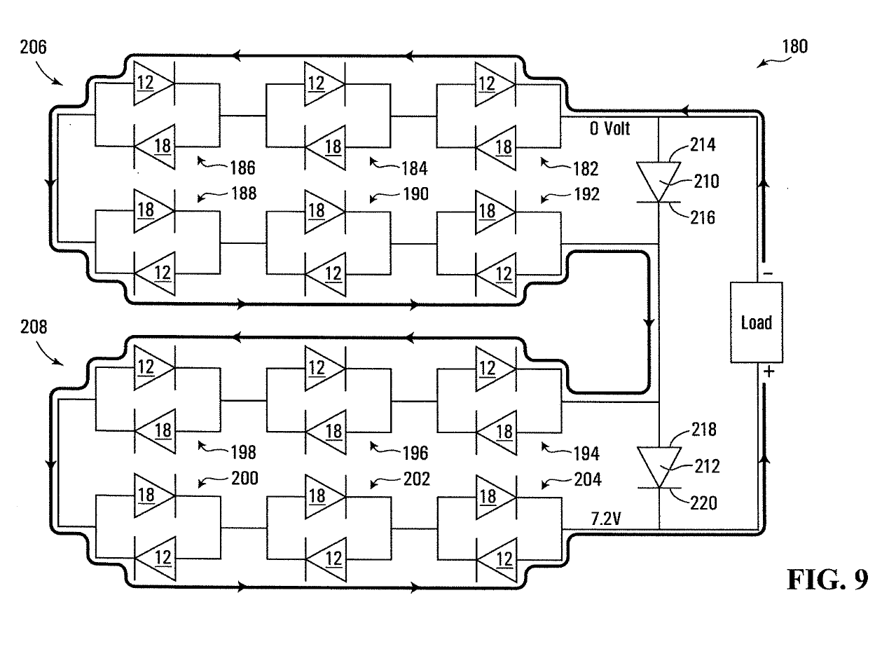

Referring to FIG. 9, a photovoltaic module apparatus for generating electric current from light energy is shown generally at 180 and includes a plurality of series-connected PV cell apparatuses 182, 184, 186, 188, 190, 192, 194, 196, 198, 200, 202, and 204. Each PV cell apparatus 186 to 204 is as described in connection with FIG. 1, and includes a solar cell 12 and a bypass diode 18.

In this embodiment, the PV cell apparatuses 186 to 204 are arranged into a plurality of series-connected groups, each comprised of six series connected PV cell apparatuses. For example, a first group 206 is comprised of PV cell apparatuses 182 to 192 and a second group 208 is comprised of PV cell apparatuses 194 to 204. Each respective group 206 and 208 has a group bypass diode 210 and 212 respectively which are connected to first and last PV cell apparatuses of each group. For example, an anode of the first group bypass diode 210 is connected to the first PV apparatus 182 of the first group 206 and the cathode 216 of the first group bypass diode 210 is connected to the last PV cell apparatus 92 of the first group 206. Similarly, an anode 218 of the second group bypass diode 212 is connected to the first PV apparatus 194 of the second group 208 and a cathode 220 of the second group bypass diode 212 is connected to the last PV apparatus 204 of the second group 208.

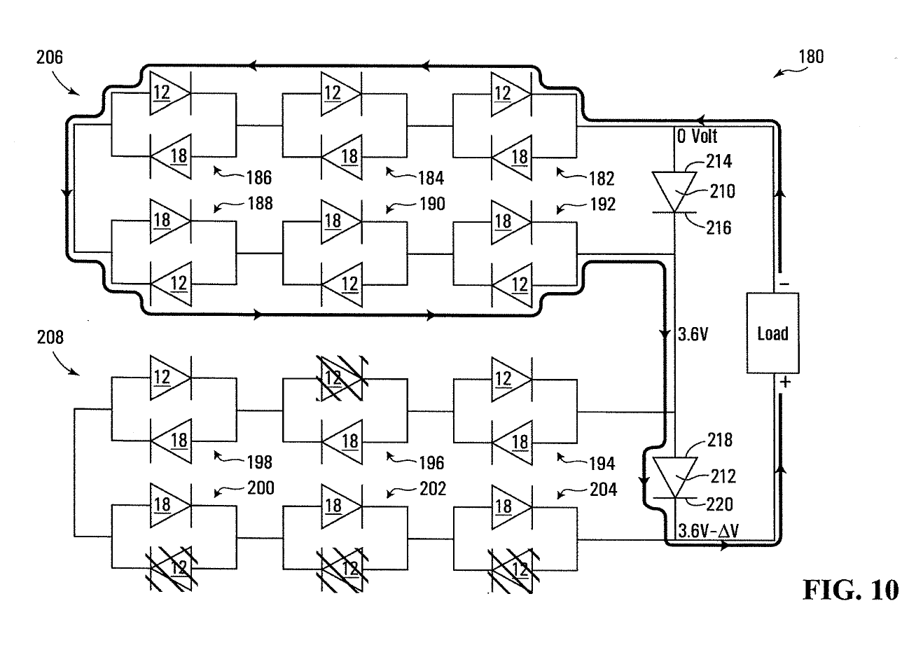

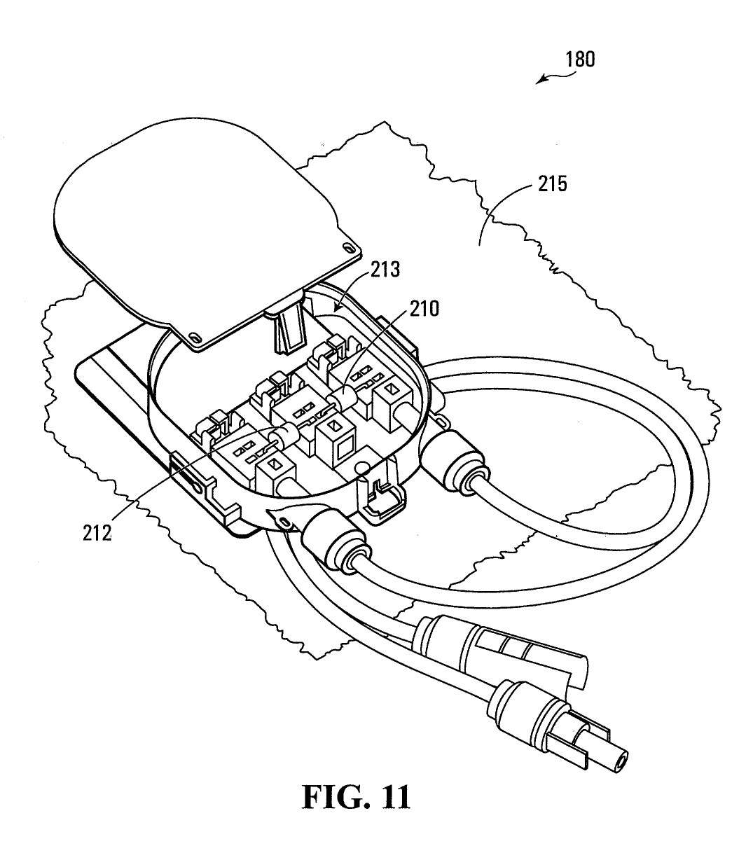

Effectively, when 0.5N+1 solar cells in a group (206 or 208) are shaded, the group bypass diode (210 or 212) associated with that group conducts current produced by the remaining group(s) to bypass the group having shaded solar cells. For example, referring to FIG. 10, in the event that four solar cells 12 of the apparatuses comprising the second group 208 become shaded, the voltage drop across the group as a whole will exceed the forward bias voltage of the second group bypass diode 212 thereby turning on the second group bypass diode and shunting current away from the second group and through the second group bypass diode. It will be appreciated that the first and second group bypass diodes 210 and 212 may be required to conduct a relatively high current and withstand the resulting heat generated thereby. Referring to FIG. 11, these group bypass diodes 210 and 212 may be conventional high powered diodes may be positioned inside a conventional junction box 213 on a back side 215 of the PV module 180 in the conventional manner.

Referring back to FIGS. 9 and 10, it will be appreciated that without the group bypass diodes 210 and 212, the two groups of PV apparatuses 206 and 208 act as a series connected string of PV apparatuses. If one cell in this series connected string becomes shaded, it no longer contributes power to the system and becomes a slight power sink due to losses imposed by conducting current through the associated bypass diode 18. Thus the effect of shading is more than simply the loss of contributed power to the overall system. As a rule of thumb, the losses imposed by any given bypass diode are almost equal to the amount of power that would otherwise have been available from the solar cell if it were fully illuminated. Therefore when a cell is shaded there is a power loss of about twice the power that would have been provided by the solar cell if it were not shaded.

It was discovered that by grouping the solar cells into groups and connecting separate bypass diodes as shown in FIGS. 9 and 10, when 0.5 N+1 solar cells in the group are shaded, the power losses exceed the power contribution that would otherwise have been provided by the group and the group becomes a net drain on the system. However, the group bypass diode bypassing the group begins to conduct and effectively shunts current around the offending group to reduce the negative effect of the shaded or partially shaded cells of the group. The overall output of the PV module is thus reduced less than it would have been if the group diodes had not been employed, when 0.5N+1 solar cells of the group are shaded.

The above described embodiments may provide a practical and inexpensive way of installing bypass diodes on a solar cell, especially since fragments of solar cell wafers can be used as bypass diodes and since no special processing techniques are required other than to adhesively adhere electrically insulating films and solder wires to various surfaces of the various components, which can be done quite easily and efficiently by employing conventional vacuum or hot roll lamination techniques. Since the bypass diodes in the embodiments described are relatively large compared to conventionally used diodes such as those described in the background section of this document, the solar cell is more amenable to vacuum or hot roll lamination since the pressure due to these processes is spread out over the entire large surface of the bypass diode rather than focused on a point such as would be case with some of the prior art bypass diodes. Since the pressure is spread out over a large area, the possibility of breaking the solar cell during vacuum or hot roll lamination is significantly reduced.

The above described embodiments may provide efficient protection of PV modules against shading and reduces the risk of damage to a shaded solar cell due to overheating.

The use of the group diodes as described enables continued collection of electric power from a group of PV cells provided fewer than 0.5 N+1 solar cells are shaded. This enables power to be generated by a group even though a few solar cells of the group are shaded, which enables the total generated kWa per year to be substantially higher than with conventional systems.

While specific embodiments of the invention have been described and illustrated, such embodiments should be considered illustrative of the invention only and not as limiting the invention as construed in accordance with the accompanying claims.

1. A shading protected solar cell apparatus for use in a solar cell system, the apparatus comprising:
a solar cell having a front side current collector and a back side current collector;
a bypass diode closely adjacent said back side current collector, said bypass diode having a front side current collector and a back side current collector;
a first electrical coupling for electrically coupling said front side current collector of said bypass diode to said back side current collector of said solar cell;
a second electrical coupling for electrically coupling said back side current collector of said bypass diode to said front side current collector of said solar cell, said first and second electrical couplings cooperating to enable a current generated by non-shaded solar cells in said system to be shunted through said bypass diode when said solar cell is shaded; and
a thermal coupling thermally coupling said bypass diode to a back side of said solar cell such that heat generated in said bypass diode due to current shunted through said bypass diode is dissipated by said solar cell sufficiently to avoid burning said solar cell or said bypass diode when said solar cell is shaded.

2. The apparatus of claim 1 wherein said bypass diode includes a silicon wafer fragment, said front and back sides of said bypass diode being on opposite sides of said silicon wafer fragment.

3. The apparatus of claim 1 wherein said front side current collector of said bypass diode is generally planar.

4. The apparatus of claim 2 wherein said silicon wafer fragment is formed from the same crystal as said solar cell.

5. The apparatus of claim 1 wherein said solar cell has a surface area and wherein said bypass diode has a surface area between about 5% to about 25% of said surface area of said solar cell.

6. The apparatus of claim 5 wherein said bypass diode has a surface area of about 10% of the surface area of said solar cell.

7. The apparatus of claim 3 wherein said first electrical coupling comprises a first electrically insulating film having first and second adjacent portions each having a first adhesive coating thereon, said first electrical coupling further comprising a first plurality of wires having first and second portions secured to said first and second portions respectively of said electrically insulating film by said first adhesive coating, and wherein said first adhesive coating adhesively secures said first portion of said first electrically insulating film to said front side current collector of said bypass diode and wherein said first portion of said first plurality of wires is soldered to said front side current collector of said bypass diode.

8. The apparatus of claim 7 further comprising a first bus bar having first and second oppositely facing surfaces, and wherein said second portion of said first electrically insulating film is secured to said first surface of said first bus bar by said first adhesive coating and wherein said second portion of said plurality of wires is soldered to said first surface of said first bus bar.

9. The apparatus of claim 8 wherein said first surface of said first bus bar generally faces a back side of said solar cell.

10. The apparatus of claim 9 wherein said second oppositely facing surface of said first bus bar generally faces away from said solar cell and wherein said first electrical coupling further comprises a second electrically insulating film having first and second adjacent portions each having a second adhesive coating thereon and a second plurality of wires having first and second portions secured to said first and second portions respectively of said second electrically insulating film by said second adhesive coating, and wherein said second adhesive coating adhesively secures said first portion of said second electrically insulating film to said second surface of said first bus bar and wherein said first portion of said second plurality of wires is soldered to said second surface of said first bus bar.

11. The apparatus of claim 10 wherein said second portion of said second electrically insulating film is secured by said second adhesive coating to said back side current collector of said solar cell and wherein said second portion of said second plurality of wires is soldered to said back side current collector of said solar cell.

12. The apparatus of claim 7 wherein said first electrically insulating flexible film has first and second oppositely facing surfaces, said first adhesive coating being on said first surface and wherein said thermal coupling comprises a thermal adhesive between said second surface of said first electrically insulating film and said back side current collector on said back side of said solar cell to secure said bypass diode to said solar cell while providing for heat transfer therebetween.

13. The apparatus of claim 12 wherein said second electrical coupling comprises a third electrically insulating film having first and second adjacent portions each having a third adhesive coating thereon and a third plurality of wires having first and second portions secured to said first and second portions respectively of said third electrically insulating film by said third adhesive coating, and wherein said third adhesive coating adhesively secures said first portion of said third electrically insulating film to said back side current collector of said bypass diode and wherein said first portion of said third plurality of wires is soldered to said back side current collector of said bypass diode.

14. The apparatus of claim 13 further including a second bus bar having first and second oppositely facing surfaces, said second portion of said third electrically insulating film being adhesively secured to said first surface of said second bus bar by said third adhesive coating and said second portion of said third plurality of wires being soldered to said first surface of said second bus bar.

15. The apparatus of claim 14 further comprising a fourth transparent electrically insulating film having first and second adjacent portions each having a fourth adhesive coating thereon and a fourth plurality of wires having first and second portions secured to said first and second portions respectively of said fourth transparent electrically insulating film by said fourth adhesive coating, and wherein said fourth adhesive coating adhesively secures said first portion of said fourth transparent electrically insulating film to said second surface of said second bus bar and wherein said first portion of said fourth plurality of wires is soldered to said second surface of said second bus bar.

16. The apparatus of claim 15 wherein said second portion of said fourth transparent electrically insulating film is adhesively secured to said front side current collector of said solar cell and wherein said second portion of said wires of said fourth plurality of wires is soldered to said front side current collector of said solar cell.

17. The apparatus of claim 11 wherein said second plurality of wires includes a third portion soldered to a bus bar of an adjacent apparatus.

18. A system comprising a plurality of apparatuses as claimed in claim 17.

19. The apparatus of claim 1 wherein said solar cell, said bypass diode, said first and second electrical couplings and said thermal coupling are configured to act as a modular self-protected solar cell apparatus.

20. The apparatus of claim 1 wherein at least one of a length and a width of said bypass diode is approximately the same as a corresponding one of a length and a width of said solar cell.

21. A method for protecting a solar cell against effects caused by shading, in a solar cell system, the method comprising:
electrically coupling a back side current collector of a bypass diode to a front side of the solar cell and electrically coupling a front side current collector of said bypass diode to a back side current collector of the solar cell to enable a current generated by non-shaded solar cells in said solar cell system to be shunted through said bypass diode when the solar cell is shaded; and
disposing said bypass diode closely adjacent said back side current collector of said solar cell and thermally coupling said bypass diode to said back side current collector of said solar cell such that heat generated in said bypass diode due to current shunted through said bypass diode is dissipated by said solar cell sufficiently to avoid burning said solar cell or said bypass diode when said solar cell is shaded.

22. The method of claim 21 wherein electrically coupling comprises causing a first adhesive coating on a first electrically insulating film to adhesively secure a first portion of said first electrically insulating film to said front side current collector of said bypass diode and soldering a first portion of a first plurality of wires embedded in said first adhesive coating to said front side current collector of said bypass diode.

23. The method of claim 22 further comprising causing said first adhesive coating to secure a second portion of said first electrically insulating film to a first surface of a first bus bar and soldering a second portion of said first plurality of wires to said first surface of said first bus bar.

24. The method of claim 23 further comprising causing said first surface of said first bus bar to generally face toward a back side of said solar cell.

25. The method of claim 24 further comprising causing a second oppositely facing surface of said first bus bar to generally face away from said back side of said solar cell.

26. The method of claim 25 further comprising causing a second adhesive coating on a second electrically insulating film to adhesively secure a first portion of said second electrically insulating film to a second surface of said first bus bar and soldering said first portion of said second plurality of wires to said second surface of said first bus bar.

27. The method of claim 26 further comprising causing said second adhesive coating to adhesively secure a second portion of said second electrically insulating film to said back side current collector of said solar cell and soldering a second portion of said second plurality of wires to said back side current collector of said solar cell.

28. The method of claim 22 wherein thermally coupling comprises applying a thermal adhesive between a surface of said first electrically insulating film and a back side of said solar cell to secure said bypass diode to said solar cell while providing for heat transfer therebetween.

29. The method of claim 28 further comprising causing a third adhesive coating to mechanically secure a first portion of a third electrically insulating film to said front side surface of said bypass diode and soldering a first portion of said third plurality of wires to said front side current collector of said bypass diode.

30. The method of claim 29 further comprising causing said third adhesive coating to adhesively secure a second portion of said third electrically insulating film to a first surface of a second bus bar and soldering a second portion of said third plurality of wires to said first surface of said second bus bar.

31. The method of claim 30 further comprising causing a fourth adhesive coating to adhesively secure a first portion of a fourth transparent electrically insulating film to a second surface of said second bus bar and soldering a first portion of a fourth plurality of wires on said fourth transparent electrically insulating film to said second surface of said second bus bar.

32. The method of claim 31 further comprising causing said fourth adhesive coating to adhesively secure a second portion of said fourth plurality of wires to said front side current collector of said solar cell and soldering a second portion of said wires of said fourth plurality of wires to said front side current collector of said solar cell.

33. The method of claim 32 further comprising soldering a third portion of said second plurality of wires to a second bus bar of an adjacent apparatus.

34. Use of at least a portion of a first solar cell as a bypass diode for a second solar cell, where the second solar cell is series connected to other solar cells a system of solar cells, by electrically coupling a back side current collector of the at least a portion of the first solar cell to a front side current collector of the second solar cell and electrically coupling a front side current collector of the at least a portion of the first solar cell to a back side current collector of the second solar cell to enable a current generated by non-shaded solar cells in said system to be shunted through said at least a portion of the first solar cell when the second solar cell is shaded;
disposing said bypass diode closely adjacent said back side current collector; and
thermally coupling said at least a portion of the first solar cell to said back side of said second solar cell such that heat generated in said at least a portion of the first solar cell due to current shunted through said at least a portion of the first solar cell is dissipated by said second solar cell sufficiently to avoid burning said at least a portion of the first solar cell or the second solar cell when said second solar cell is shaded.

35. A method of protecting a solar cell against shading in a system of series-connected solar cells exposed to light, the method comprising:
electrically coupling a back side current collector of at least a portion of a first solar cell configured to act as a bypass diode to a front side current collector of a second solar cell configured to convert light energy into electrical energy, wherein said second solar cell is series connected to other solar cells in said system, where said other solar cells are configured to convert light energy into electrical energy,
electrically coupling a front side current collector of the at least a portion of the first solar cell to a back side current collector of the second solar cell such that a current generated by non-shaded solar cells in said system is shunted through said at least a portion of the first solar cell when the second solar cell is shaded;
disposing said bypass diode closely adjacent said back side current collector of said solar cell; and
thermally coupling said at least a portion of the first solar cell to said back side of said second solar cell such that heat generated in said at least a portion of the first solar cell due to current shunted through said at least a portion of the first solar cell is dissipated by said second solar cell sufficiently to avoid burning said at least a portion of the first solar cell or the second solar cell when said second solar cell is shaded.

36. A method of generating electric current from light energy, the method comprising:
connecting in series, a plurality of photovoltaic (PV) cell apparatuses to form a PV module, each PV cell apparatus comprising:
a solar cell having a front side current collector and a back side current collector;
a bypass diode closely adjacent said back side current collector, said bypass diode having a front side current collector and a back side current collector;
a first electrical coupling for electrically coupling said front side current collector of said bypass diode to said back side current collector of said solar cell;
a second electrical coupling for electrically coupling said back side current collector of said bypass diode to said front side current collector of said solar cell, said first and second electrical couplings cooperating to enable a current generated by non-shaded solar cells in said system to be shunted through said bypass diode when said solar cell is shaded; and
a thermal coupling thermally coupling said bypass diode to the back side of said solar cell such that heat generated in said bypass diode due to current shunted through said bypass diode is dissipated by said solar cell sufficiently to avoid burning said solar cell or said bypass diode when said solar cell is shaded.

37. An apparatus for generating electric current from light energy, the apparatus comprising:
a photovoltaic (PV) module comprising a plurality of series-connected PV cell apparatuses, each PV cell apparatus comprising:
a solar cell having a front side current collector and a back side current collector;
a bypass diode closely adjacent said back side current collector, said bypass diode having a front side current collector and a back side current collector;
a first electrical coupling for electrically coupling said front side current collector of said bypass diode to said back side current collector of said solar cell;
a second electrical coupling for electrically coupling said back side current collector of said bypass diode to said front side current collector of said solar cell, said first and second electrical couplings cooperating to enable a current generated by non-shaded solar cells in said system to be shunted through said bypass diode when said solar cell is shaded; and
a thermal coupling thermally coupling said bypass diode to the back side of said solar cell such that heat generated in said bypass diode due to current shunted through said bypass diode is dissipated by said solar cell sufficiently to avoid burning said solar cell or said bypass diode when said solar cell is shaded.

38. The apparatus of claim 37 wherein said solar cell, said bypass diode, said first and second electrical couplings and said thermal coupling are configured to act as a modular self-protected solar cell apparatus

39. The apparatus of claim 37 wherein at least one of a length and a width of said bypass diode is approximately the same as a corresponding one of a length and a width of said solar cell.

40. A method of generating electric current from light energy, the method comprising:
connecting in series, a plurality of photovoltaic (PV) cell apparatuses to form a PV module, each PV cell apparatus comprising:
a solar cell having a front side current collector and a back side current collector;
a bypass diode closely adjacent said back side current collector, said bypass diode having a front side current collector and a back side current collector;
a first electrical coupling for electrically coupling said front side current collector of said bypass diode to said back side current collector of said solar cell;
a second electrical coupling for electrically coupling said back side current collector of said bypass diode to said front side current collector of said solar cell, said first and second electrical couplings cooperating to enable a current generated by non-shaded solar cells in said system to be shunted through said bypass diode when said solar cell is shaded; and
a thermal coupling thermally coupling said bypass diode to the back side of said solar cell such that heat generated in said bypass diode due to current shunted through said bypass diode is dissipated by said solar cell sufficiently to avoid burning said solar cell or said bypass diode when said solar cell is shaded;
grouping said PV cell apparatuses into a plurality of series connected groups each comprised of N series connected PV cell apparatuses; and
connecting a respective group bypass diode to first and last PV cell apparatuses of each group such that when 0.5 N+1 solar cells in a group are shaded, the bypass diode associated with said group conducts current produced by the remaining groups to bypass the group having shaded solar cells.

41. The method of claim 40 further comprising connecting said bypass diodes associated with respective groups to a heatsink.

42. The method of claim 41 further comprising placing said PV apparatuses into a PV module mount for holding said PV apparatuses.

43. The method of claim 42 wherein connecting said bypass diodes to a heatsink comprises connecting said bypass diodes associated with respective groups to an exterior surface of said PV module mount

44. An apparatus for generating electric current from light energy, the apparatus comprising:
a photovoltaic (PV) module comprising a plurality of series-connected PV cell apparatuses, each PV cell apparatus comprising:
a solar cell having a front side current collector and a back side current collector;
a bypass diode closely adjacent said back side current collector, said bypass diode having a front side current collector and a back side current collector;
a first electrical coupling for electrically coupling said front side current collector of said bypass diode to said back side current collector of said solar cell;
a second electrical coupling for electrically coupling said back side current collector of said bypass diode to said front side current collector of said solar cell, said first and second electrical couplings cooperating to enable a current generated by non-shaded solar cells in said system to be shunted through said bypass diode when said solar cell is shaded; and
a thermal coupling thermally coupling said bypass diode to the back side of said solar cell such that heat generated in said bypass diode due to current shunted through said bypass diode is dissipated by said solar cell sufficiently to avoid burning said solar cell or said bypass diode when said solar cell is shaded;
said PV cell apparatuses being arranged into a plurality of series connected groups each comprised of N series connected PV cell apparatuses; and
respective group bypass diodes electrically connected to first and last PC cell apparatuses of each group such that when 0.5 N+1 solar cells in a group are shaded, the bypass diode associated with said group conducts current produced by the remaining groups to bypass the group having shaded solar cells.

45. The apparatus of claim 44 wherein said bypass diodes associated with respective groups are connected to a heatsink.

46. The apparatus of claim 45 further comprising a PV module mount for holding said PV apparatuses.

47. The apparatus of claim 46 wherein said heatsink includes said PV module mount.

48. The apparatus of claim 44 wherein said solar cell, said bypass diode, said first and second electrical couplings and said thermal coupling are configured to act as a modular self-protected solar cell apparatus

49. The apparatus of claim 44 wherein at least one of a length and a width of said bypass diode is approximately the same as a corresponding one of a length and a width of said solar cell.
